(19) United States
(12) Patent Application Publication
(10) Pub. No.: US 2026/0245245 A1
(43) Pub. Date: Aug. 20, 2026

(54) DETECTION APPARATUS, DETECTION METHOD, STORAGE MEDIUM, LITHOGRAPHY APPARATUS, AND ARTICLE MANUFACTURING METHOD

(71) Applicant: CANON KABUSHIKI KAISHA, Tokyo (JP)

(72) Inventors: NATSUKO NINOMIYA, Tochigi (JP); SHINICHI EGASHIRA, Tochigi (JP)

(21) Appl. No.: 19/542,865

(22) Filed: Feb. 18, 2026

(30) Foreign Application Priority Data
Feb. 20, 2025 (JP) 2025-026030

(51) Int. Cl. G06T 7/73; G03F 9/00; G06T 7/00; H10P 72/50

(52) U.S. Cl. CPC G06T 7/74; G03F 9/7003; G03F 9/7088; G03F 9/7092; G06T 7/0004; H10P 72/53; G06T 2207/30148

(57) ABSTRACT

A detection apparatus for detecting a position of a mark formed on a substrate is provided. The apparatus includes a processor configured to perform processing of detecting the position of the mark by template matching including calculation of a degree of correlation between an image of the mark and a template while changing a relative position between the image and the template. In the template matching, the processor determines a relative position to be set as a target of the calculation of the degree of correlation based on a result of comparing, with a threshold, feature amounts of a plurality of pixels of the image corresponding to a plurality of feature points included in the template at each of a plurality of relative positions between the image and the template.

### BACKGROUND

### Field of the Technology

The present disclosure relates to a detection apparatus, a detection method, a storage medium, a lithography apparatus, and an article manufacturing method.

### Description of the Related Art

Along with recent miniaturization and high integration of semiconductor devices such as ICs and LSIs, the accuracy and function of exposure apparatuses have been improved. Especially in aligning an original such as a mask or reticle with a substrate such as a semiconductor wafer, a technique for aligning a device pattern formed on the original with a device pattern formed on the substrate on a nanometer order is expected. As an exposure apparatus used to manufacture semiconductors and the like, an apparatus called a stepper or scanner is often used. These apparatuses sequentially transfer a pattern formed on an original (for example, a reticle) to a plurality of positions on a substrate (for example, a wafer) while moving the substrate step by step. The apparatus that collectively performs the transfer processing is called a stepper, and the apparatus that transfers the pattern while scanning a stage is called a scanner.

An example of an operation of aligning the pattern of the original with the pattern formed on the substrate is alignment of the substrate (wafer alignment). Wafer alignment is performed by exposing and transferring a circuit pattern of an original and an alignment mark (to be also simply referred to as a mark hereinafter) onto a substrate at the same time, optically detecting, when exposing a circuit pattern of the next original onto the substrate, the position of the mark transferred to the substrate, and aligning the substrate with the original. The mark is detected by, for example, enlarging the mark by a microscope, capturing the mark, and detecting the position of the image of the mark.

To detect the position of a detection target object, a method called template matching can be used. Template matching is a method of calculating an index indicating the correlation between an image including a detection target object and a template at each of a plurality of relative positions while changing the relative position between the image and the template, and detecting the position of the detection target object based on the relative position where the correlation is highest (see, for example, Japanese Patent No. 5414921 and Japanese Patent Laid-Open No. 2012-048593). In this specification, high correlation means that the detection target object in the image and the template match with higher accuracy.

Examples of the index indicating the correlation are the Sum of Squared Differences (SSD) for obtaining the sum of the squares of the differences between the template and the image and the Sum of Absolute Differences (SAD) for obtaining the sum of the absolute values of the differences. In addition, as the index indicating the correlation, a normalized correlation to be described later can be used.

However, in a case where a defect occurs in a part of an alignment mark in a manufacturing process, position detection by template matching may not be performed correctly, causing a detection error.

### SUMMARY

The present disclosure provides a position detection technique robust against a defect in a target object of template matching.

The present disclosure in one aspect provides a detection apparatus for detecting a position of a mark formed on a substrate, including a processor configured to perform processing of detecting the position of the mark by template matching including calculation of a degree of correlation between an image of the mark and a template while changing a relative position between the image and the template, wherein in the template matching, the processor determines a relative position to be set as a target of the calculation of the degree of correlation based on a result of comparing, with a threshold, feature amounts of a plurality of pixels of the image corresponding to a plurality of feature points included in the template at each of a plurality of relative positions between the image and the template.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view showing the configuration of a position detection apparatus;

FIG. 2A is a view exemplifying an image IM, a search range AR, and a target object MA;

FIG. 2B is a view exemplifying a template TP;

FIG. 3 is a view exemplifying a scanning route in the search range by template matching;

FIG. 4 is a flowchart exemplifying the procedure of conventional template matching;

FIG. 5 is a view for explaining a method of calculating a pixel differential value;

FIG. 6 is a view for explaining a method of determining a defect in a target object;

FIG. 7 is a flowchart illustrating a detection method of detecting the position of the target object;

FIG. 8 is a view exemplifying the relationship between a main template and a sub-template;

FIG. 9 is a flowchart illustrating a detection method of detecting the position of the target object; and

FIG. 10 is a view showing the configuration of an exposure apparatus.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### First Embodiment

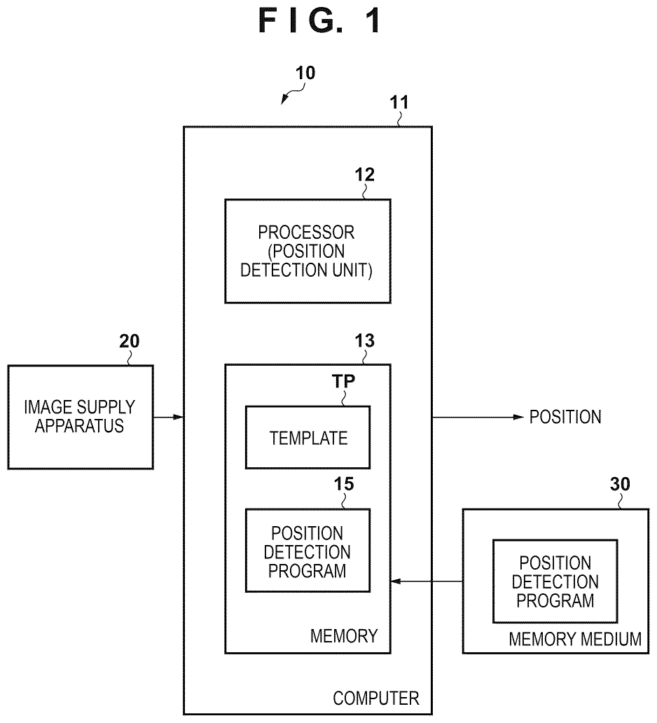

FIG. 1 shows an example of the configuration of a position detection apparatus 10 according to the embodiment. The position detection apparatus 10 is a detection apparatus that detects the position of a mark formed on a substrate. The position detection apparatus 10 can be formed by a computer 11 (information processing apparatus). The computer 11 can include a processor 12 (CPU) and a memory 13 (storage device). The memory 13 stores a template TP used for template matching and a position detection program 15 in addition to an Operating System (OS) (not shown). The template TP can be rewritable. The position detection program 15 can be provided from an external memory medium 30 storing the position detection program to the computer 11 via a memory reader (not shown) or a communication line (not shown), and installed in the memory 13. The processor 12 operates based on the position detection program 15 stored in the memory 13 to cause the computer 11 to operate as a position detection apparatus or cause the processor 12 to operate as a position detection unit.

The position detection apparatus 10 detects the position of a detection target object in an image supplied from an image supply apparatus 20 by template matching using the template TP. Template matching includes calculation of a degree of correlation between the image and the template while shifting the search position of the image of the mark. The processor 12 performs processing of detecting the position of the mark by this template matching. The detection target object can be, for example, the image of the mark. The image supply apparatus 20 can be, for example, an image capturing unit (camera). The image capturing unit can form, for example, a part of an alignment scope that captures an image of the mark (alignment mark) provided on the substrate.

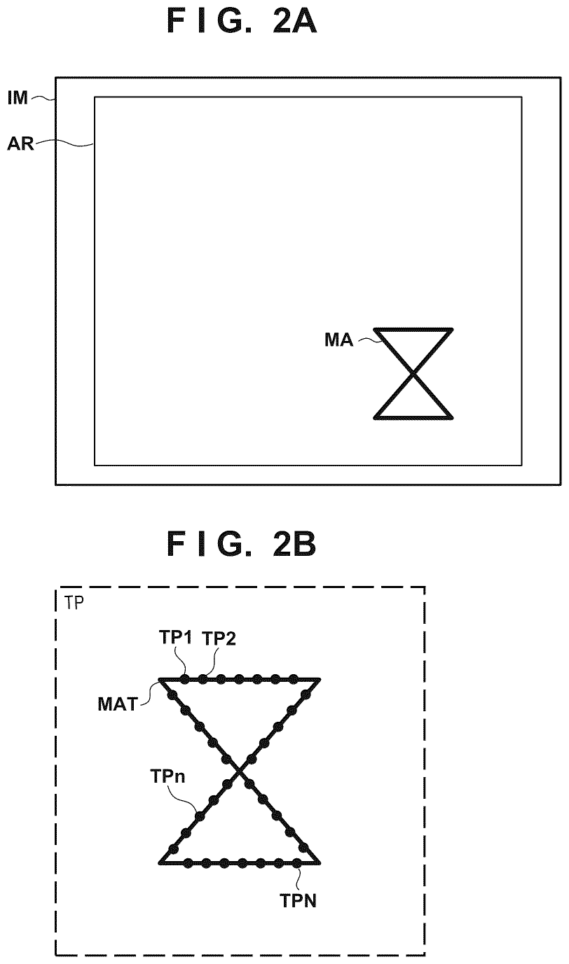

FIG. 2A exemplifies a search range AR of an image IM including a target object MA (for example, a mark image) to be detected. FIG. 2B exemplifies the template TP.

The template TP can include N feature points TP1 to TPN indicating a feature of a comparison image MAT corresponding to the target object MA to be detected. Each of the plurality of feature points TP1 to TPN can be formed by coordinates (position) in the template TP and a value at the coordinates. In the example shown in FIG. 2B, the feature points TP1 to TPN are arranged in an edge portion of the comparison image MAT.

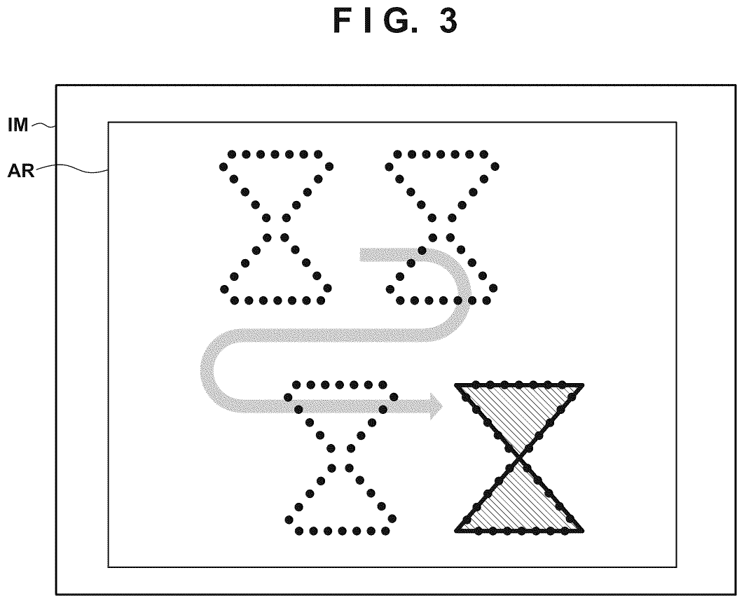

The image IM can be supplied from the image supply apparatus 20. The image IM can be formed by a plurality of pixels, and a position in the image can be represented by pixel coordinates (position). To detect the position of the target object MA in the search range AR, the position detection apparatus 10 can be configured to calculate the correlation between the image IM and the template TP at each position in the search range AR while scanning the template TP with respect to the search range AR. In other words, the position detection apparatus 10 can be configured to calculate the correlation between the image IM and the template TP at each of a plurality of relative positions while changing the relative position of the template TP with respect to the search range AR (FIG. 3). Note that the search range AR is scanned while fixing the relative positions between the feature points TP1 to TPN in the template TP. Then, the position detection apparatus 10 can be configured to detect the position of the target object MA based on the relative position where the correlation between the image IM and the template TP is highest, among the plurality of relative positions. The relative position can be, for example, the relative position between the center position of the image IM and the center position of the template TP.

### Example 1

As an example, an index (a degree of correlation) indicating the correlation between the image IM and the template TP is calculated using a Normalized Cross-Correlation (NCC) in which calculation by a normalized correlation is performed. The index may be calculated in accordance with another method such as the Sum of Absolute Differences (SAD) or Sum of Squared Differences (SSD) instead of the NCC. The calculation amount of the NCC is larger than those of the SSD and SAD, but the NCC is relatively robust against fluctuations in luminance and hence capable of stably detecting a target object. The index indicating the correlation obtained by the NCC can be defined as a degree of correlation S_NCC. The higher the degree of correlation S_NCC, the higher the correlation. That is, this means that the target object MA in the image IM and the template TP match with higher accuracy. The degree of correlation S_NCC(x, y) at a position (x, y) in the image IM is a degree of correlation when the center of the template TP is matched with the position (x, y) in the image IM. The position detection apparatus 10 can be configured to calculate the degree of correlation S_NCC(x, y) at the position (x, y) in the image IM in accordance with equation (1a) or (1b) to be described later. It may be understood that the position (x, y) in the image IM represents the relative position between the image IM and the template TP.

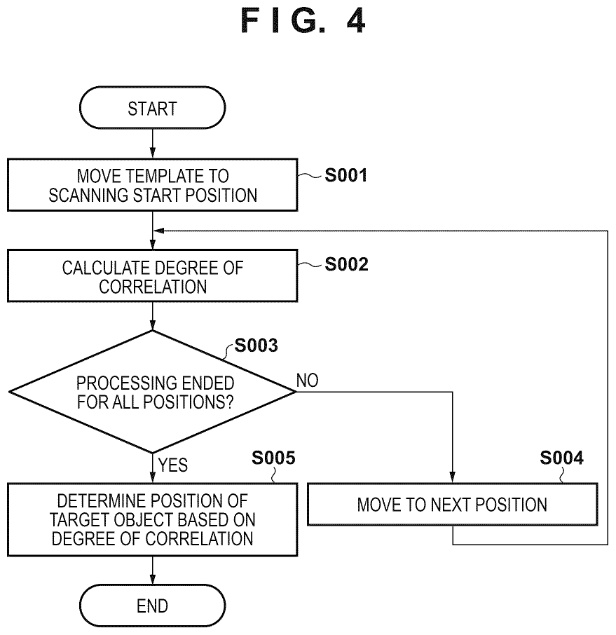

FIG. 4 is a flowchart of conventional template matching. When template matching starts, the template TP moves to a scanning start position in the search range AR in step S001. In step S002, the degree of correlation S_NCC at this position is calculated. In step S003, it is determined whether the degree of correlation S_NCC has been calculated at all the positions in the search range AR. If there is an unprocessed position in the search range AR, the template TP moves to the next relative position in step S004, and the degree of correlation S_NCC at the position is calculated (step S002). After this processing is repeated to complete calculation of the degree of correlation S_NCC at all the positions in the search range AR, the position of the target object MA is determined in step S005 based on the degree of correlation at each position.

A method of calculating the degree of correlation S_NCC at the position (x, y) in the image IM in step S002 will be described. A pixel value at the coordinates (x, y) in the image IM is defined as I(x, y), a pixel value at coordinates (i, j) in the template TP is defined as T(i, j), and the total number of pixels of the template TP is defined as N. When the coordinates of an nth feature point TPn in the template TP are represented by (tn, un), the pixel value I(x, y) at the coordinates (x, y) in the image IM is I(x+tn, y+un). The degree of correlation S_NCC is obtained by:

$$S\_NCC ( x , y ) = \frac{{\sum }_{n = 1}^{N} ( I ( x + tn , y + un ) \cdot T ( tn , un ) )}{\sqrt{{\sum }_{n = 1}^{N} {( I ( x + tn , y + un ) )}^{2}} \sqrt{{\sum }_{n = 1}^{N} {( T ( tn , un ) )}^{2}}} \qquad ( 1 a )$$

The degree of correlation S_NCC can also be calculated by substituting a pixel differential value Diff for the pixel value I(x, y) and a constant T for the pixel value T(i, j) in equation (1a). When a pixel differential value at the coordinates (x, y) in the image IM is represented by Diff(x, y), the degree of correlation S_NCC is obtained by:

$$S\_NCC ( x , y ) = \frac{{\sum }_{n = 1}^{N} ( Diff ( x + tn , y + un ) \cdot T )}{\sqrt{{\sum }_{n = 1}^{N} {( Diff ( x + tn , y + un ) )}^{2}} \sqrt{{\sum }_{n = 1}^{N} {( T )}^{2}}} \qquad ( 1 b )$$

When calculating the degree of correlation S_NCC using a pixel value as a feature amount, equation (1a) is used, and when calculating the degree of correlation S_NCC using a pixel differential value as a feature amount, equation (1b) is used. A method when equation (1b) is used will be described below. A pixel differential value as a feature amount can include differential direction information and differential width information.

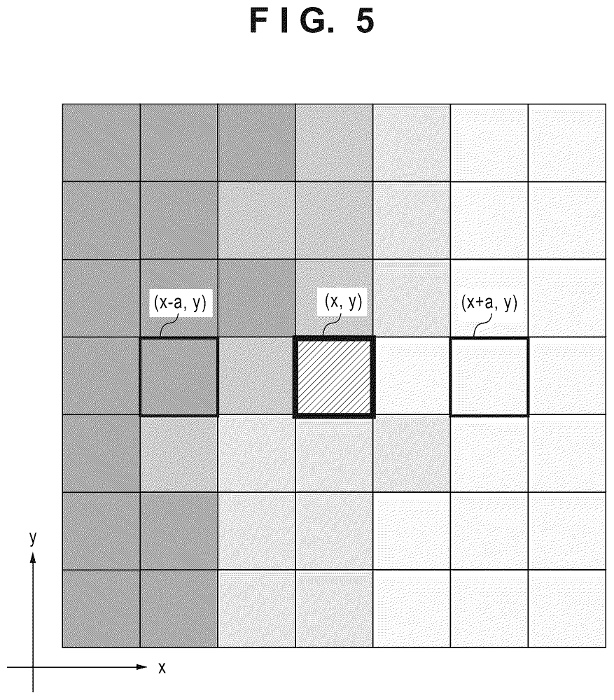

As shown in FIG. 5, when the pixel value I(x, y) at the position (x, y) in the image IM is used and the differential width is represented by a, Diff is obtained by:

$$Diff ( x , y ) = I ( x + a , y ) - I ( x - a , y ) \qquad ( 2 )$$

As shown in FIG. 5, for the pixel differential value Diff, the differential direction can be defined. When pixel differential values in the positive direction of the x-axis, the negative direction of the x-axis, the positive direction of the y-axis, and the negative direction of the y-axis are represented by Diff_XU, Diff_XD, Diff_YU, and Diff_YD, respectively, the pixel differential values can be obtained by:

$$Diff\_XU ( x , y ) = I ( x + a , y ) - I ( x - a , y ) \qquad ( 3 )$$

$$Diff\_XD ( x , y ) = I ( x - a , y ) - I ( x + a , y )$$

$$Diff\_YU ( x , y ) = I ( x , y + a ) - I ( x , y - a )$$

$$Diff\_YD ( x , y ) = I ( x , y - a ) - I ( x , y + a )$$

Note that each feature point TPn in the template TP can have direction information for determining which of equations (3) for the four directions is used to calculate the pixel differential value Diff. The direction information can arbitrarily be determined in accordance with the design of the target object MA at each feature point TPn in the template TP. For example, at each feature point TPn, one of four equations (3), which gives the largest calculation result, can be employed. The differential width a when calculating the pixel differential value Diff can also arbitrarily be determined in the same manner. In the following description, for the sake of descriptive convenience, the pixel differential value will sometimes simply be represented by Diff without specifying the differential direction.

The processor 12 calculates the degree of correlation S_NCC using equation (1a) or (1b) at each of the plurality of relative positions while changing the relative position between the image IM and the template TP. Changing the relative position of the template TP with respect to the image IM is synonymous with moving the template TP within the search range AR. To do this, a raster scan may be used, and a step distance at this time may arbitrarily be determined.

After moving the position of the template TP in step S004, the processing (steps S002, S003, and S004) of calculating the degree of correlation S_NCC is repeated. Thus, the processor 12 obtains the degree of correlation S_NCC as an index indicating the correlation between the template TP and the image IM at each of the plurality of relative positions. This operation is equivalent to obtaining the degree of correlation between the template TP and the image IM at each of the plurality of positions (x, y) in the image IM.

The degree of correlation S_NCC at a position where there is no target object in the image IM is low, the degree of correlation S_NCC at a position where there exists a pattern similar to the target object MA is high, and the degree of correlation S_NCC at a position where the target object and the template TP overlap each other is highest.

The position detection apparatus 10 determines, as the position (x, y)=(X, Y) of the target object MA, the relative position (x, y)=(X, Y) where the correlation between the image IM and the template TP is highest, among the plurality of relative positions (x, y) (step S005).

However, if the target object MA is defective, the pixel differential value Diff is not calculated correctly and becomes an excessively small value, and S_NCC calculated using the pixel differential value Diff also becomes a small value. Therefore, although the target object MA and the template TP overlap each other, the degree of correlation S_NCC is not highest in some cases.

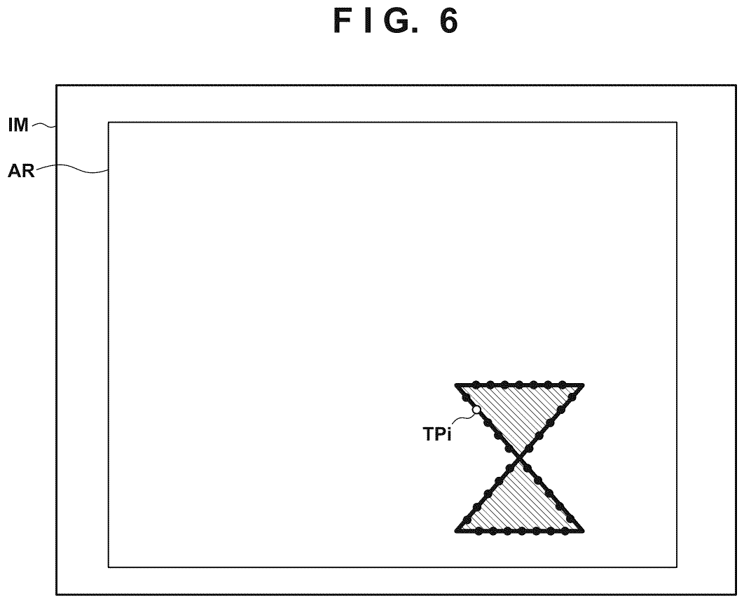

To cope with this, in this embodiment, a case where a pixel differential value Diff(x+ti, y+ui) at a feature point TPi(ti, ui) in the template TP is smaller than a threshold is detected. In this case, as shown in FIG. 6, the feature point TPi(ti, ui) in the template TP, that is, a position (x+ti, y+ui) in the image IM is determined as a defective portion. Then, in calculation of the degree of correlation using equation (1a) or (1b), the pixel differential value Diff(x+ti, y+ui) at the defective portion is excluded from the calculation target. This can prevent the degree of correlation S_NCC from becoming excessively small, and detect the position of the target object MA.

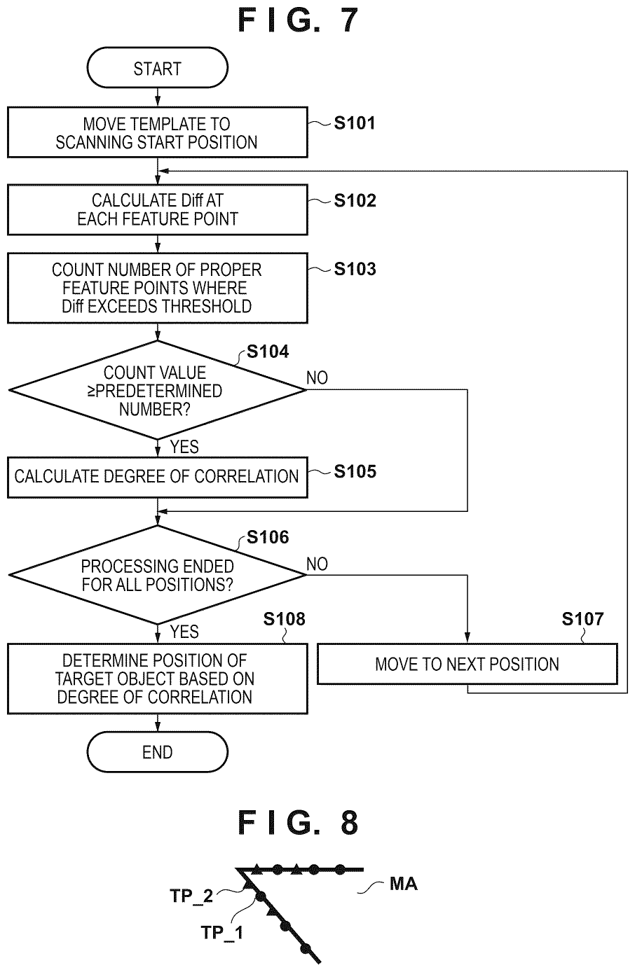

A detection method of detecting the position of the target object (the mark formed on the substrate) according to this embodiment will be described below. In template matching, the processor 12 compares, with a threshold, the feature amounts of the plurality of pixels in the image IM corresponding to the plurality of feature points included in the template TP at each of the plurality of relative positions between the image IM and the template TP. After that, based on the result of the comparison, the processor 12 determines the relative position where the degree of correlation is to be calculated. A practical example of the detection method will be described below with reference to FIG. 7. FIG. 7 is a flowchart illustrating the detection method of detecting the position of the target object (the mark formed on the substrate). In step S101, the processor 12 adjusts the relative position of the template TP with respect to the search range AR so that the template TP is located at the scanning start position in the search range AR. In step S102, the processor 12 calculates the pixel differential value Diff of each of the plurality of pixels corresponding to the plurality of feature points TPi at that position using equations (3). In step S103, the processor 12 counts the number of proper feature points at each of which the pixel differential value Diff exceeds the threshold, among the plurality of pixels in the image IM corresponding to the plurality of feature points included in the template. In step S104, the processor 12 determines whether a count value obtained in step S103, that is, the number of proper feature points at each of which the pixel differential value Diff exceeds the threshold is equal to or larger than a predetermined number. Only if the count value is equal to or larger than the predetermined number, the process advances to step S105, and the processor 12 calculates the degree of correlation. After that, the process advances to step S106. If the count value is smaller than the predetermined number, step S105 is skipped. In step S106, the processor 12 determines whether all the positions in the search range AR have been processed. If there is an unprocessed position in the search range AR, the processor 12 adjusts, in step S107, the relative position between the search range AR and the template TP so that the template TP is located at the next position in the search range AR. After that, the process returns to step S102, and the processing for the position is repeated. If the processing of all the positions in the search range AR is complete (YES in step S106), the process advances to step S108, and the processor 12 determines the position of the target object MA based on the degree of correlation.

The threshold of Diff used in step S103 can be determined based on the pixel differential value in a region including the template TP. An image region including the template TP at the position (x, y) in the image IM is represented by AR_T. When the pixel differential value in the region AR_T is represented by Diff_A, a standard deviation σ can be obtained by.

$$σ = \sqrt{\frac{1}{N} \sum {( Diff\_A ( x , y ) - \overline{Diff\_A ( x , y )} )}^{2}} \qquad ( 4 )$$

This standard deviation σ can be used to set the threshold to σ*k (k is an arbitrary integer of 1 or more). That is, when Diff>σ*k, this feature point can be defined as a proper feature point without any defect. Alternatively, arbitrary integers a and b of 1 or more may be used to set a threshold range, and this feature point may be defined as a proper feature point when σ*a<Diff<σ*b.

In addition, the pixel differential value Diff_A used to calculate the standard deviation σ may be the pixel differential value at an arbitrary position in the region AR_T or may be limited to a pixel differential value Diff(tn, un) at each feature point in the template TP. The pixel differential value Diff_A of equation (4) may be replaced with a pixel I.

With the above processing, only the relative position where the count value (that is, the number of proper feature points at each of which the feature amount exceeds the threshold, among the plurality of pixels in the image IM corresponding to the plurality of feature points forming the template TP) obtained in step S103 is equal to or larger than the predetermined number is set as the calculation target of the degree of correlation in step S105. In other words, if the number of proper feature points at each of which the pixel differential value Diff exceeds the threshold is smaller than the predetermined number, the feature point is determined to be located at the defective portion, and the pixel differential value Diff is excluded from the calculation target of the degree of correlation (NO in step S104).

Note that when excluding the feature point determined to be located at the defective portion from calculation of the degree of correlation S_NCC, if the number of feature points to be excluded is too large, it is impossible to obtain the degree of correlation S_NCC correctly. Therefore, it is determined whether the number of feature points used to calculate the degree of correlation S_NCC is equal to or larger than the threshold (step S104). The threshold may be defined by a fixed ratio to the total number N of feature points. Alternatively, each feature point TPn in the template TP may be classified in accordance with the direction information of the feature point TPn, the number of proper feature points may be counted for each piece of direction information, and it may be determined whether each count value is equal to or larger than a predetermined number.

### Example 2

As is apparent from equations (1a) and (1b) as the calculation formulas of the degree of correlation S_NCC, if the number of measurement points in the search range AR or the total number N of feature points in the template TP is large, the calculation amount increases. In recent years, since there is a need to improve the measurement accuracy of template matching, and the image resolution is high, the calculation time of this method of obtaining the degree of correlation by scanning an image may be prolonged. To shorten the calculation time, the feature points in the template TP are arranged only in the feature portion of the target object MA, and the number of feature points is minimized.

However, in Example 1 described above, if the number of defects at the feature points in the feature portion of the target object MA is large, the number of feature points at each of which Diff is equal to or larger than the threshold decreases, thereby disabling measurement.

To cope with this, when the template including the minimum number of feature points described above is set as a main template TP_1, a sub-template TP_2 in which feature points are arranged near the feature points along the feature portion of the target object MA is prepared. The main template and the sub-template are different in terms of the arrangement of the feature points. For example, as shown in FIG. 8, the feature points of the sub-template TP_2 are arranged near the feature points of the template TP_1 at the edge of a corner portion which is a feature portion as a portion characterizing the shape of the target object MA. The main template TP_1 can include N feature points TP_11 to TP_1N, and the sub-template TP_2 can include M feature points TP_21 to TP_2M. In an example, M>N.

In template matching using the main template TP_1, a desired degree of correlation cannot be calculated in the process of the flowchart (FIG. 7) according to Example 1 and position specification of the target object MA may not be completed normally. In this case, in Example 2, template matching is performed again using the sub-template TP_2. This makes it possible to calculate a matching position.

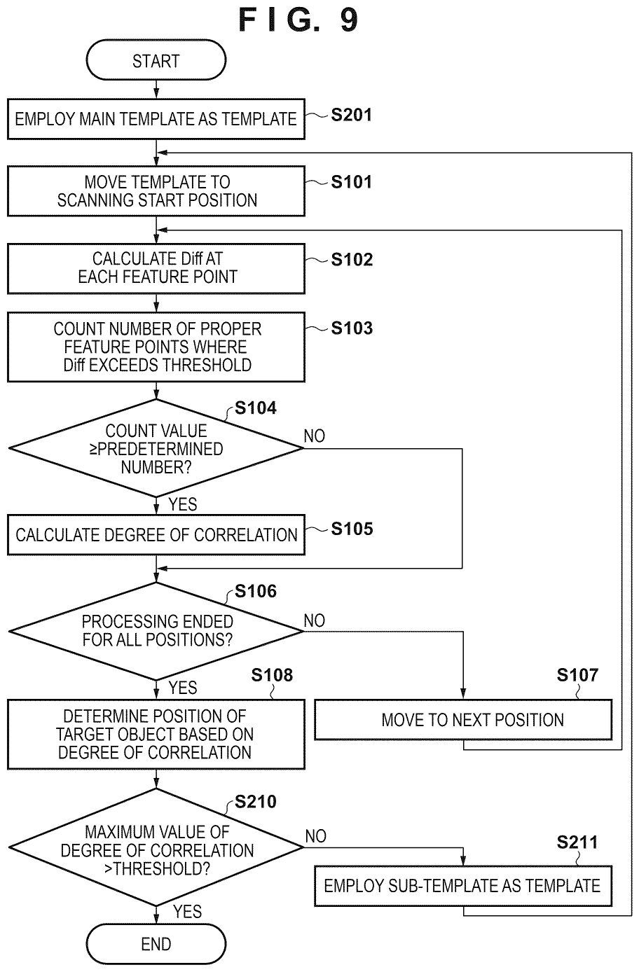

FIG. 9 is a flowchart according to Example 2. The same reference symbols as in FIG. 7 denote the same processing blocks and a description thereof will be omitted. In step S201, the processor 12 employs the main template TP_1 as the template TP. After that, the first template matching is performed using the main template TP_1. In the first template matching, after the end of determination of the position of the target object in step S108, the processor 12 determines in step S210 whether the maximum value of the degree of correlation S_NCC at the position of the target object MA determined in step S108 exceeds a threshold (second threshold). If the maximum value of the degree of correlation S_NCC does not exceed the second threshold, it can be determined that the position of the target object MA is detected erroneously. In this case, it is determined that the position specification is not completed normally, and the process advances to step S211. In step S211, the processor 12 employs the sub-template TP_2 as the template TP. After that, the process returns to step S101, and the second template matching is performed using the sub-template TP_2. Note that there can be variations in employing the sub-template TP_2 as the template TP, as follows.

(1) Only the feature points in the sub-template TP_2 are employed as the template TP.

(2) The feature points in the main template TP_1 and the sub-template TP_2 are employed as the template TP.

(3) The feature points in the main template TP_1 and the sub-template TP_2 after removing the defective portions determined in step S104 are employed as the template TP. More specifically, the feature points obtained by excluding, from the feature points in the main template TP_1, inappropriate feature points at each of which the feature amount does not exceed the threshold, and the feature points in the sub-template TP_2 are employed as the template TP.

(4) The feature points in the main template TP_1 after removing the defective portions determined in step S104 and the feature points near the defective portions in the sub-template TP_2 are employed as the template TP. More specifically, the feature points obtained by excluding, from the feature points in the main template TP_1, inappropriate feature points at each of which the feature amount does not exceed the threshold, and the feature points near the inappropriate feature points among the feature points in the sub-template are employed as the template TP.

The operation of employing the feature points in the sub-template TP_2 as the template TP in step S211 may be performed when the condition that the number of feature points used to calculate the degree of correlation S_NCC in step S105 is equal to or larger than the threshold is not satisfied. In this case, the processing may be redone from step S102 or S103.

### Second Embodiment

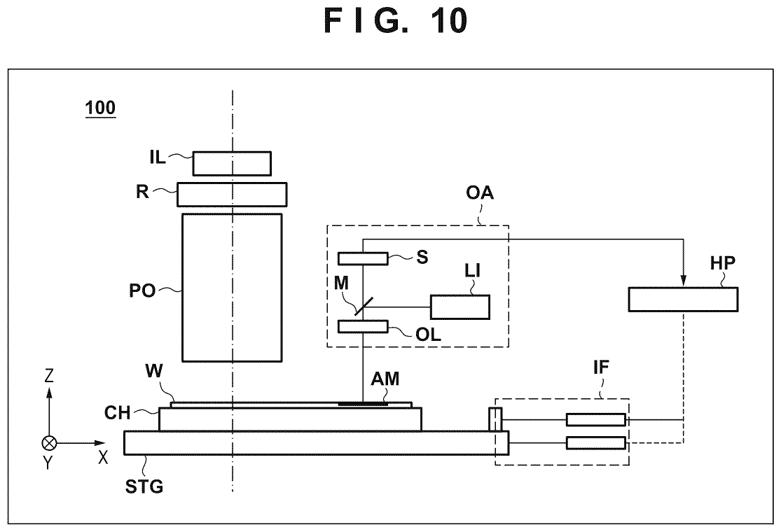

An example of applying the above-described position detection apparatus 10 to an exposure apparatus 100 serving as a lithography apparatus will be described with reference to FIG. 10. The position detection apparatus 10 is also applicable to another lithography apparatus such as an imprint apparatus or charged particle writing apparatus.

The exposure apparatus 100 is an apparatus that aligns a reticle R as an original and a wafer W as a substrate with each other, and irradiates the reticle R with exposure light by an illuminating system IL, thereby transferring a pattern of the reticle R onto the wafer W via a projection optical system PO. The wafer W is held by a chuck CH. The chuck CH is mounted on a stage STG movable in the X, Y, and Z directions. The position of the stage STG is measured by an interferometer IF. The stage STG is driven based on the measurement result of the position of the stage. A plurality of alignment marks AM for aligning the wafer W are formed on the wafer W. An alignment detection system OA optically detects the alignment mark AM. When detecting the alignment mark AM by the alignment detection system OA, the stage STG is driven so that the alignment mark AM falls within the detection range of the alignment detection system OA.

The alignment detection system OA includes an optical system such as an illumination light source LI and an objective lens OL. Illumination light emitted by the illumination light source LI is reflected by a half mirror M via the optical system, and illuminates the alignment mark AM. Reflected scattered light from the alignment mark AM forms an image IMG including the alignment mark AM on the imaging surface of an image sensor S such as a CCD or CMOS sensor via the optical system. The image IMG is transferred to a host control apparatus HP. The host control apparatus HP serving as the position detection apparatus 10 detects the position of the alignment mark AM on the wafer W using the image IMG in accordance with the method described in the first embodiment. After that, the host control apparatus HP performs exposure based on array design information of shot regions formed on the wafer W, which has been input in advance, the position information of the alignment mark AM, and the position information of the stage STG obtained from the interferometer IF.

### <Embodiment of Article Manufacturing Method>

An article manufacturing method according to an embodiment of the present disclosure is suitable for manufacturing an article, for example, a microdevice such as a semiconductor device, or an element having a fine structure. The article manufacturing method according to the embodiment includes a step of transferring a pattern of an original onto a substrate using the above-described lithography apparatus, and a step of processing the substrate onto which the pattern has been transferred in the above step. In addition, the manufacturing method includes other well-known steps (oxidation, deposition, vapor deposition, doping, planarization, etching, resist removal, dicing, bonding, packaging, and the like). The article manufacturing method according to this embodiment is more advantageous than the conventional methods in at least one of the performance, quality, productivity, and production cost of the article.

According to the above-described various embodiments, there is provided a position detection technique robust against a defect in a target object of template matching.

### OTHER EMBODIMENTS

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-026030, filed Feb. 20, 2025 which is hereby incorporated by reference herein in its entirety.

What is claimed is:

1. A detection apparatus for detecting a position of a mark formed on a substrate, comprising:
a processor configured to perform processing of detecting the position of the mark by template matching including calculation of a degree of correlation between an image of the mark and a template while changing a relative position between the image and the template,
wherein in the template matching, the processor determines a relative position to be set as a target of the calculation of the degree of correlation based on a result of comparing, with a threshold, feature amounts of a plurality of pixels of the image corresponding to a plurality of feature points included in the template at each of a plurality of relative positions between the image and the template.

2. The apparatus according to claim 1, wherein in the template matching, the processor
counts, at each of the plurality of relative positions between the image and the template, the number of proper feature points at each of which the feature amount exceeds the threshold, among the plurality of pixels of the image corresponding to the plurality of feature points included in the template, and
sets, as the target of the calculation of the degree of correlation, only the relative position where the number of proper feature points is not smaller than a predetermined number, among the plurality of relative positions.

3. The apparatus according to claim 2, wherein the feature amount is one of a pixel value and a pixel differential value.

4. The apparatus according to claim 2, wherein the feature amount is a pixel differential value, and includes differential direction information and differential width information.

5. The apparatus according to claim 1, wherein when σ represents a standard deviation of the feature amounts in a region including the template, the threshold is given by σ*k (k is an integer not less than 1).

6. The apparatus according to claim 1, wherein the processor calculates the degree of correlation using one of an NCC, an SAD, and an SSD.

7. The apparatus according to claim 1, wherein the template matching includes scanning the image while fixing relative positions between the plurality of feature points included in the template.

8. The apparatus according to claim 4, wherein the processor classifies the plurality of feature points in accordance with direction information of each feature point, counts the number of proper feature points for each piece of direction information, and determines whether each count value is not smaller than the predetermined number.

9. The apparatus according to claim 1, wherein the processor performs first template matching using a main template, and performs, in a case where a maximum value of calculated degrees of correlation does not exceed a second threshold, second template matching using a sub-template different from the main template in terms of an arrangement of feature points.

10. The apparatus according to claim 9, wherein the second template matching is template matching using only the feature points in the sub-template.

11. The apparatus according to claim 9, wherein the second template matching is template matching using the feature points in the main template and the feature points in the sub-template.

12. The apparatus according to claim 9, wherein the second template matching is template matching using the feature points obtained by excluding, from the feature points in the main template, inappropriate feature points at each of which the feature amount does not exceed the threshold, and the feature points in the sub-template.

13. The apparatus according to claim 9, wherein the second template matching is template matching using the feature points obtained by excluding, from the feature points in the main template, inappropriate feature points at each of which the feature amount does not exceed the threshold, and the feature points near the inappropriate feature points among the feature points in the sub-template.

14. A detection method of detecting a position of a mark formed on a substrate, comprising:
performing processing of detecting the position of the mark by template matching including calculation of a degree of correlation between an image of the mark and a template while changing a relative position between the image and the template,
wherein in the performing the processing, a relative position to be set as a target of the calculation of the degree of correlation is determined based on a result of comparing, with a threshold, feature amounts of a plurality of pixels of the image corresponding to a plurality of feature points included in the template at each of a plurality of relative positions between the image and the template.

15. A computer-readable storage medium storing a program for causing a computer to execute a detection method of detecting a position of a mark formed on a substrate, the program causing the computer to execute:
performing processing of detecting the position of the mark by template matching including calculation of a degree of correlation between an image of the mark and a template while changing a relative position between the image and the template,
wherein in the performing the processing, a relative position to be set as a target of the calculation of the degree of correlation is determined based on a result of comparing, with a threshold, feature amounts of a plurality of pixels of the image corresponding to a plurality of feature points included in the template at each of a plurality of relative positions between the image and the template.

16. A lithography apparatus comprising:
a detection apparatus defined in claim 1; and
a stage configured to move while holding a substrate,
wherein the stage is aligned based on a position of a mark detected by the detection apparatus, and
a pattern of an original is transferred onto the substrate held by the aligned stage.

17. An article manufacturing method comprising:
forming a pattern on a substrate using a lithography apparatus defined in claim 16; and
processing the substrate on which the pattern is formed,
wherein an article is manufactured from the processed substrate.
